(19) United States
(12) Patent Application Publication
(10) Pub. No.: US 2023/0411369 A1
(43) Pub. Date: Dec. 21, 2023

(54) PHOTONICS PACKAGING WITH HIGH-DENSITY ROUTING

(71) Applicant: Intel Corporation, Santa Clara, CA (US)

(72) Inventors: Omkar G. Karhade, Chandler, AZ (US); Kaveh Hosseini, Livermore, CA (US); Chia-Pin Chiu, Tempe, AZ (US); Tim T. Hoang, San Jose, CA (US); Tolga Acikalin, San Jose, CA (US); Cooper S. Levy, Portland, OR (US)

(73) Assignee: Intel Corporation, Santa Clara, CA (US)

(21) Appl. No.: 17/841,451

(22) Filed: Jun. 15, 2022

(51) Int. Cl. H01L 25/16; G02B 6/42; H01L 23/538; H01L 23/498; H01L 23/00

(52) U.S. Cl. CPC H01L 25/167; G02B 6/4274; H01L 23/5381; H01L 2224/16225; H01L 23/49811; H01L 24/16; H01L 23/5383

(57) ABSTRACT

In one embodiment, an integrated circuit package includes a package substrate with a cavity, an integrated circuit device, a bridge, a photonic integrated circuit (PIC), and an electronic integrated circuit (EIC). The integrated circuit device is electrically coupled to the package substrate. The bridge and the PIC are in the cavity of the package substrate, and the bridge is electrically coupled to the package substrate. The EIC is above, and electrically coupled to, the bridge and the PIC.

### STATEMENT REGARDING FEDERALLY SPONSORED RESEARCH AND DEVELOPMENT

This invention was made with Government support under Agreement No. HR00111830002 awarded by the United States Department of Defense. The Government has certain rights in the invention.

### BACKGROUND

The development of high-performance optical transceivers is crucial to meet the continuously increasing data rate demands of modern data centers and computing systems. For example, optical transceivers can be included with traditional computing components to enable them to communicate using high-speed optical interconnects rather than traditional electrical interconnects. These optical transceivers typically include electronic integrated circuits (EICs) and photonic integrated circuits (PICs). In the design of these transceivers, smaller EICs are desirable to reduce power requirements, provide faster bandwidth, reduce cost, and decrease the overall package size. However, smaller EICs also reduce the footprint of the EIC on the substrate, which can lead to routing congestion and may limit the number of I/O and power lines that can be accessed from the substrate.

### BRIEF DESCRIPTION OF THE DRAWINGS

FIGS. 1A-B illustrate an example embodiment of a photonics package with a cavity bridge for routing to/from electronic integrated circuits.

FIGS. 2A-B illustrate an example embodiment of a photonics package with a photonic integrated circuit cavity bridge for routing to/from electronic integrated circuits.

FIGS. 3A-B illustrate an example embodiment of a photonics package with a cavity bridge for routing to/from electronic integrated circuits and an XPU.

FIGS. 4A-B illustrate an example embodiment of a photonics package with a photonic integrated circuit cavity bridge for routing to/from electronic integrated circuits and an XPU.

FIGS. 5A-F illustrate various stages of an example packaging process for packaging an integrated circuit device with photonics circuitry.

FIG. 6 illustrates an example process flow for packaging an integrated circuit device with photonics circuitry.

FIG. 7 illustrates an example system with computing components that are packaged with optical transceivers in multi-chip packages.

FIG. 8 is a top view of a wafer and dies that may be included in a microelectronic assembly, in accordance with any of the embodiments disclosed herein.

FIG. 9 is a cross-sectional side view of an integrated circuit device that may be included in a microelectronic assembly, in accordance with any of the embodiments disclosed herein.

FIG. 10 is a cross-sectional side view of an integrated circuit device assembly that may include a microelectronic assembly, in accordance with any of the embodiments disclosed herein.

FIG. 11 is a cross-sectional view of an example bridge embedded within a first substrate component.

FIG. 12 is a block diagram of an example electronic device that may include a microelectronic assembly, in accordance with any of the embodiments disclosed herein.

### DETAILED DESCRIPTION

The development of high-performance optical transceivers is crucial to meet the continuously increasing data rate demands of modem data centers and computing systems. For example, optical input/output (I/O) chiplets can be co-packaged with traditional computing components (e.g., processors, accelerators, FPGAs, switches, memory/storage, other ASIC nodes) in multi-chip packages (MCP) to enable those components to communicate using high-speed optical interconnects rather than traditional electrical interconnects.

These optical I/O chiplets typically include electronic integrated circuits (EICs) and photonic integrated circuits (PICs). In a high-bandwidth photonic package, smaller EICs are desirable to reduce power requirements, provide faster bandwidth, reduce cost, and decrease the overall package size. However, smaller EICs also reduce the footprint of the EIC on the package substrate, which can lead to routing congestion and may limit the number of EIC I/O and power lines that can be accessed from the substrate (e.g., for testing and power supply). As a result, developers are forced to choose between the following design tradeoffs: (i) use a smaller EIC and limit the I/O count to the EIC (with limited test functionality and power delivery); or (ii) use a larger EIC and take a hit on power, bandwidth, and cost.

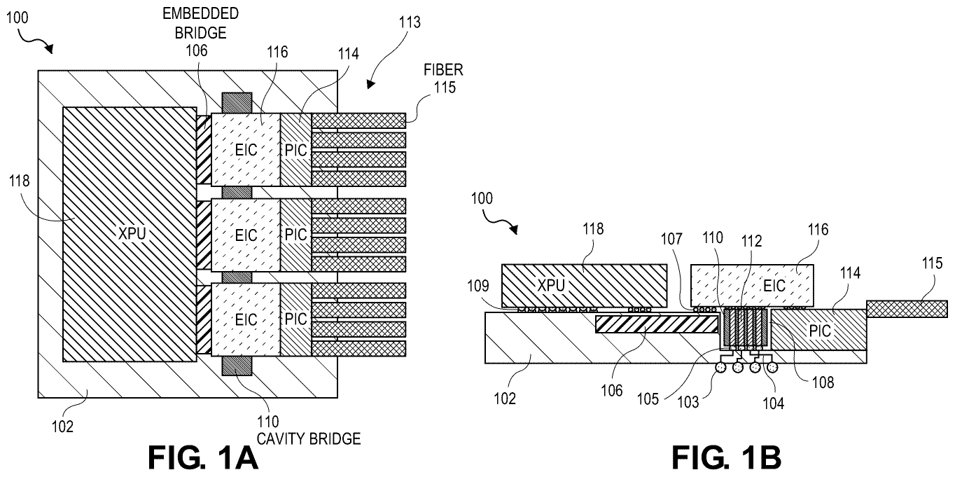

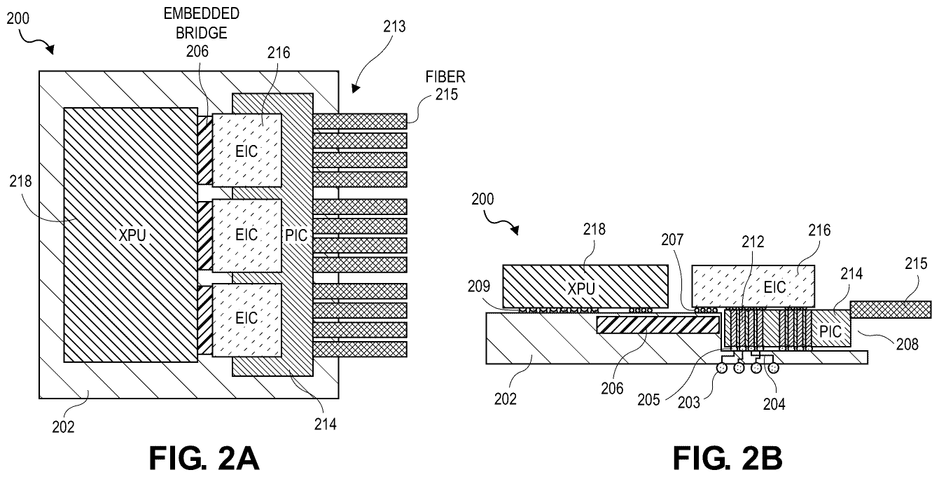

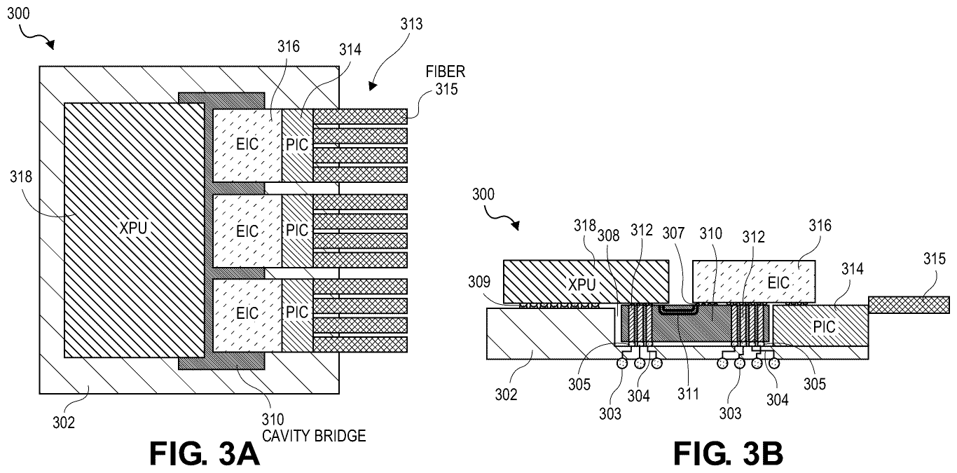

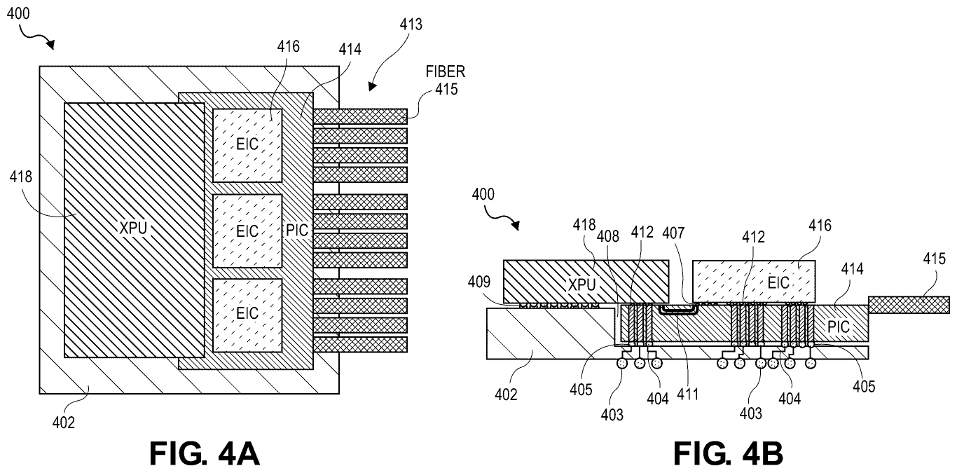

Accordingly, this disclosure presents various photonics package architectures that leverage in-cavity interconnects (e.g., bridges/PICs within a substrate cavity) to enable tight-pitch, high-density routing to the EIC and other components in a photonics package. In some embodiments, for example, a photonics package may leverage one of the following designs to eliminate routing congestion issues:
1. A cavity bridge with through-hole vias under the EIC to enable tight-pitch high-density routing (e.g., FIGS. 1A-B).
2. A PIC cavity bridge (PIC-CB) with through-hole vias extending under the EIC for routing purposes (e.g., FIGS. 2A-B).
3. A cavity bridge with through-hole vias extending under both the EIC and the packaged computing component (e.g., XPU) to enable for tight-pitch routing (e.g., FIGS. 3A-B) (e.g., replacing embedded bridges or interposers used to connect the packaged component).
4. A PIC-CB with through-hole vias extending under the EIC and the packaged computing component (e.g., XPU) for tight-pitch routing (e.g., FIGS. 4A-B).

The described embodiments provide various advantages. For example, the described embodiments solve routing congestion problems in photonics packages by incorporating in-cavity interconnects with fine-pitch routing lines that can be spaced much closer together compared to routing lines in the package substrate. In this manner, routing lines in a typical package substrate with a relatively large pitch (e.g., ˜21 microns (μm)) can be replaced with routing lines in an in-cavity interconnect (e.g., on a silicon or glass substrate) with a much smaller pitch (e.g., ˜1-4 μm). As a result, the described embodiments enable high-density routing in photonics packages, which increases the maximum number of power and I/O lines that can be included in the design. Further, the described embodiments are compatible with any fiber termination design, including both vertical and edge emitting PICs and their respective fiber terminations, among other examples.

FIGS. 1A-B illustrate an example embodiment of a photonics package 100 with a cavity bridge (CB) 110 for routing to/from electronic integrated circuits (EICs) 116. In the illustrated embodiment, rather than connecting the EICs 116 directly to the package substrate 102 (e.g., for power and I/O), the EICs 116 are indirectly connected to the package substrate 102 through the cavity bridge 110, which supports a much finer routing pitch than the package substrate 102. As a result, through-hole vias 112 can be spaced much closer together in the cavity bridge 110 compared to the package substrate 102, which eliminates routing congestion and enables high-density routing in the package 100.

In the illustrated embodiment, for example, the photonics package 100 includes an XPU 118 and an optical transceiver 113 on a package substrate 102. The XPU 118 generally refers to any computing component packaged with the optical transceiver 113 in the photonics package 100 to enable the component to communicate using fiber optics. For example, the XPU 118 may include any type or combination of processing units or other computing components, including, but not limited to, processors, processor cores, central processing units (CPUs), graphics processing units (GPUs), vision processing units (VPUs), tensor processing units (TPUs), application-specific integrated circuits (ASICs), field-programmable gate arrays (FPGAs), switches, network interface controllers (NICs), persistent storage devices, and memory.

The optical transceiver 113 is used to send and/or receive optical signals on behalf of the XPU 118. In the illustrated embodiment, the optical transceiver 113 includes multiple photonic integrated circuits (PICs) 114 with attached fiber arrays 115 and multiple electronic integrated circuits (EICs) 116. In particular, each PIC 114 is attached to a collection of glass fibers 115, which may be collectively referred to as a fiber array or fiber array unit. Each PIC 114 also has an associated EIC 116. The PICs 114 are used to send and receive optical signals over the optical fibers 115, and the EICs 116 are driver circuits used to control the PICs 114. In some embodiments, the PICs 114 may include components such as laser diodes (LD)/modulators (LD-MOD) (e.g., for transmitting optical signals), photodiodes (PD) (e.g., for receiving optical signals), optical couplers, collimation/refocusing lenses, reflection mirrors, and so forth. Moreover, in some embodiments, the EICs 116 may include components such as transimpedance amplifiers (TIA), driver circuits, and so forth.

The package substrate 102 has conductive contacts 103 (e.g., balls, pads) on the bottom surface, which are connected to conductive traces 104 patterned in the substrate 102 and serve as a second level interconnect (SLI) to a next level component, such as a printed circuit board (e.g., a motherboard) and/or another integrated circuit package. The package substrate 102 also has a cavity 108 formed in a portion of the substrate surface, which houses the cavity bridge (CB) 110 and the photonic integrated circuits (PICs) 114, as described below.

The cavity bridge (CB) 110 resides in the cavity 108 of the substrate 102 and serves as a bridge between the conductive traces 104 in the substrate 102 (e.g., power and I/O traces) and the electronic integrated circuits (EICs) 116. In the illustrated embodiment, for example, the cavity bridge 110 is a substrate with through-hole vias (THVs) 112, such as a silicon substrate with through-silicon vias (TSVs) 112 or a glass substrate with through-glass vias (TGVs) 112. Moreover, the vias 112 in the cavity bridge 110 are connected to conductive contacts 107 on the EICs 116 and conductive contacts 105 in the cavity 108 of the substrate 102 (which in turn are connected to the power and I/O traces 104 in the substrate 102 and the second level interconnect 103).

The photonic integrated circuits (PICs) 114 also reside in the cavity 108 of the substrate 102. In the illustrated embodiment, the PICs 114 are bonded to the surface of the substrate 102 within the cavity 108, adjacent to the cavity bridge 110, and a fiber array 115 is attached to each PIC 114.

The electronic integrated circuits (EICs) 116 are above, and electrically connected to, the cavity bridge 110, the PICs 114, and the substrate 102. For example, each EIC 116 is directly above the cavity bridge 110 and extends partially over one of the PICs 114 and the top surface of the substrate 102. Further, each EIC 116 is electrically connected to the cavity bridge 110, one of the PICs 114, and the substrate 102. For example, the conductive contacts 107 (e.g., bumps/micro-bumps) on the bottom surface of each EIC 116 are connected to conductive contacts (not shown) on the top surfaces of the cavity bridge 110, one of the PICs 114, and the substrate 102, which serves as a first level interconnect (FLI) for each EIC 116.

In this manner, the EICs 116 are indirectly connected to the power and I/O traces 104 in the package substrate 102 via the cavity bridge 110. Moreover, the cavity bridge substrate 110 is made of materials that support a much finer routing pitch than the package substrate 102, which enables the through-hole vias 112 to be spaced much closer together in the cavity bridge 110 compared to the package substrate 102, thus eliminating routing congestion. In some embodiments, for example, the cavity bridge 110 may be a silicon or glass substrate and the package substrate 102 may be an organic substrate. Moreover, vias can be formed with a finer pitch in a silicon or glass substrate compared to an organic substrate. As a result, more routing lines can be embedded in the cavity bridge 110 to route EIC 116 signals, which eliminates routing congestion limitations in the high-density routing region under the EIC 116.

Further, since each EIC 116 is also connected to one of the PICs 114, each PIC 114 is indirectly connected to the power and I/O traces 104 in the package substrate 102 through its associated EIC 116 (and in turn through the cavity bridge 110).

The XPU 118 is electrically connected to the top surface of the package substrate 102 (e.g., outside of or external to the cavity 108). For example, conductive contacts 109 (e.g., bumps/micro-bumps) on the bottom surface of the XPU 118 are attached to conductive contacts (not shown) on the top surface of the substrate 102, which serves as a first level interconnect (FLI) for the XPU 118.

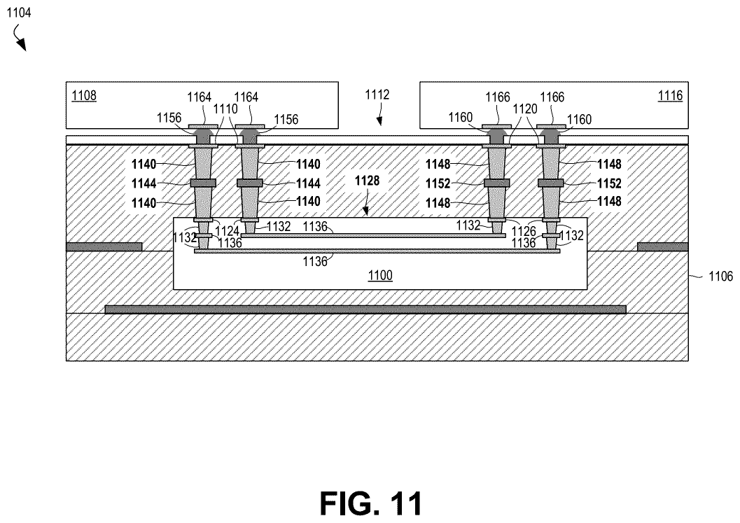

The EICs 116 and the XPU 118 are indirectly connected to each other via embedded bridges 106 in the substrate 102. In the illustrated embodiment, for example, the package substrate 102 includes multiple embedded bridges 106, each of which is embedded in the substrate 102 and serves as an interconnect between one of the EICs 116 and the XPU 118. For example, each EIC 116 is connected to one of the embedded bridges 106 through its electrical connections 107 to the top surface of the substrate 102. Similarly, the XPU 118 is connected to all of the embedded bridges 106 through its electrical connections 109 to the top surface of the substrate 102. In some embodiments, the embedded bridges 106 may be similar to the embedded bridge 1100 of FIG. 11. For example, each embedded bridge 106 may be an embedded multi-die interconnect bridge (EMIB) that serves as an interconnect between one of the EICs 116 and the XPU 118.

The design of photonics package 100 provides various advantages. For example, the cavity bridge 110 with through-hole vias 112 can deliver power to the EIC 116 and directly connect I/O to the substrate 102. Moreover, the cavity bridge (CB) 110 offers 1-4 μm pitch routing compared to ˜20 μm pitch routing in the package substrate 102. Further, the EIC-to-CB bump pitch connection can be ˜40-60 μm compared to an EIC-to-substrate pitch of ˜100+μm. As a result, this design enables additional I/O and power delivery traces to be included in the package 100 without increasing the size of the EIC 116. Further, this design also makes it possible to have different thickness cavities for the cavity bridge 110 versus the PIC 114. In some embodiments, for example, the CB cavity may be ˜100 μm to allow TSVs and solder joints, while the PIC cavity may be less than 100 μm for top surface or edge coupled fiber or greater than 200 μm for V-groove-based fiber attach.

FIGS. 2A-B illustrate an example embodiment of a photonics package 200 with a photonic integrated circuit cavity bridge (PIC-CB) 214 for routing to/from electronic integrated circuits (EICs) 216. Photonics package 200 is similar to photonics package 100, except the PICs 114 and cavity bridge 110 in photonics package 100 have been integrated or combined into a PIC 214 with an embedded cavity bridge (PIC-CB) in photonics package 200. For example, instead of having a standalone cavity bridge (CB) 110, routing congestion is addressed in photonics package 200 by extending the PIC 214 under the EICs 216 and adding through-hole vias 212 and conductive contacts to the PIC 214. In this manner, the PIC 214 is directly connected to the conductive traces 204 in the substrate 202 for power and I/O (e.g., via the conductive contacts 205 in the cavity 208), and the PIC 214 also serves as an in-cavity bridge between the EICs 216 and those conductive traces 204.

In some embodiments, the components of photonics package 200 may be similar to those with similar reference numerals in photonics package 100, except as otherwise noted herein. In the illustrated embodiment, for example, the photonics package 200 includes an XPU 218 and an optical transceiver 213 on a package substrate 202 with a cavity 208. The package substrate 202 also includes conductive contacts 203 (e.g., balls, pads) below the substrate 202, conductive contacts 205 in the cavity 208, conductive traces 204 patterned in the substrate 202 (at least some of which are connected to the conductive contacts 203, 205), and multiple embedded bridges 206. The optical transceiver 213 includes a photonic integrated circuit cavity bridge (PIC-CB) 214 and multiple electronic integrated circuits (EICs) 216.

The PIC-CB 214 resides in the cavity 208 of the substrate 202 and includes typical photonic components/circuitry described herein along with multiple through-hole vias 212 to serve as a bridge within the cavity 208. The PIC-CB 214 is connected to conductive contacts 205 in the cavity 208 and conductive contacts 207 under the EICs 216. In addition, multiple fiber arrays 215 are attached to the PIC-CB 214.

Each EIC 216 includes conductive contacts 207 on its bottom surface, some of which are connected to conductive contacts on the top surface of the PIC-CB 214, and others which are connected to one of the embedded bridges 206 via conductive contacts on the top surface of the substrate 202.

The XPU 218 includes conductive contacts 209 on its bottom surface that are connected to conductive contacts on the top surface of the substrate 202, which in turn connect to the embedded bridges 206 and may also connect to other conductive traces in the substrate 202.

The design of photonics package 200 provides various advantages, including the advantages described for photonics package 100, along with additional advantages. For example, PIC power delivery is simplified by the through-hole vias and contacts in/under the PIC 214, as power is supplied directly to the PIC 214 instead of through the EIC 216. The design also provides additional space for EIC signal routing by utilizing some of the metal routing area in the PIC 214. In addition, the EIC-to-embedded-bridge and EIC-to-PIC bump pattern does not need a transition region, which enables a continuous bump pattern to be achieved and further reduces the size of the EIC. Further, the larger footprint of the PIC-CB 214 extending beyond the edges of the EIC 216 allows pitch transitions between the top and bottom sides of the PIC-CB 214.

FIGS. 3A-B illustrate an example embodiment of a photonics package 300 with a cavity bridge (CB) 310 for routing to/from electronic integrated circuits (EICs) 316 and an XPU 318. Photonics package 300 is similar to photonics package 100, except the embedded bridges 106 in photonics package 100 have been replaced by the cavity bridge 310 in photonics package 300. For example, instead of having embedded bridges 106 connecting the XPU 118 and EICs 116 in photonics package 100, the cavity bridge 310 is extended under the XPU 318 in photonics package 300, which enables the cavity bridge 310 to serve as an interconnect between the XPU 318 and the EICs 316 and also between the XPU 318 and power and I/O traces 304 in the substrate 302. For example, additional conductive traces 311 are added to the cavity bridge 310 to interconnect the XPU 318 and the EICs 316. Further, additional through-hole vias 312 are added to the portion of the cavity bridge 310 below the XPU 318, along with additional conductive traces 304 in the substrate 302 and conductive contacts 303, 305 below the substrate 302 and in the cavity 308, which enables the cavity bridge 310 to serve as a bridge between the XPU 318 and the power and I/O traces 304 in the substrate 302.

In some embodiments, the components of photonics package 300 may be similar to those with similar reference numerals in photonics package 100, except as otherwise noted herein. In the illustrated embodiment, for example, the photonics package 300 includes an XPU 318 and an optical transceiver 313 on a package substrate 302 with a cavity 308. The package substrate 302 also includes conductive contacts 303 (e.g., balls, pads) below the substrate 302, conductive contacts 305 in the cavity 308, and conductive traces 304 patterned in the substrate 302 (at least some of which are connected to the conductive contacts 303, 305). The optical transceiver 313 includes multiple photonic integrated circuits (PICs) 314 and multiple electronic integrated circuits (EICs) 316.

The PICs 314 reside in the cavity 308 of the substrate 302 and include typical photonic components/circuitry described herein. In addition, a fiber array 315 is attached to each PIC 314.

The cavity bridge 310 also resides in the cavity 308 and includes through-hole vias 312 below the EICs 316 and the XPU 318, along with conductive traces 311 connecting the EICs 316 and the XPU 318. Further, the cavity bridge 310 is connected to conductive contacts 305 in the cavity 308, conductive contacts 307 under the EICs 316, and conductive contacts 309 under the XPU 318.

Each EIC 316 includes conductive contacts 307 on its bottom surface, which are connected to the top surface of one of the PICs 314 and the top surface of cavity bridge 310.

The XPU 318 includes conductive contacts 309 on its bottom surface, which are connected to the top surface of the cavity bridge 310 and may also be connected to conductive contacts on the top surface of the substrate 302 (which may in turn connect to other conductive traces in the substrate 302).

The design of photonics package 300 provides various advantages, including the advantages described for photonics package 100, along with additional advantages. For example, this design provides additional space for EIC and XPU signal routing by extending the cavity bridge 310 under both the EIC 316 and the XPU 318, which enables high density I/O connections between the EIC 316 and XPU 318. In addition, power delivery to the XPU 318 improves with direct vertical connection through the cavity bridge 310. Further, the XPU-to-EIC connection is through the cavity bridge 310 rather than the substrate layers 302, which results in better bandwidth.

FIGS. 4A-B illustrate an example embodiment of a photonics package 400 with a photonic integrated circuit cavity bridge (PIC-CB) 414 for routing to/from electronic integrated circuits (EICs) 416 and an XPU 418. Photonics package 400 is similar to photonics package 100, except the PICs 114, cavity bridge 110, and embedded bridges 106 in photonics package 100 have been integrated or combined into a PIC 414 with an embedded cavity bridge (PIC-CB) in photonics package 400. For example, instead of having a standalone cavity bridge 110 and multiple embedded bridges 106 in photonics package 100, routing congestion is addressed in photonics package 400 by extending the PIC 414 under the EICs 416 and the XPU 418, and adding conductive traces 411, through-hole vias 412, and conductive contacts to the PIC 414, along with additional conductive traces 404 in the substrate 402 and conductive contacts 403, 405 below the substrate 402 and in the cavity 408. In this manner, the PIC 414 is directly connected to the conductive traces 404 in the substrate 402 for power and I/O (e.g., via the conductive contacts 405 in the cavity 408), and the PIC 414 also serves as an in-cavity bridge between (i) the EICs 416 and the power and I/O traces 404 in the substrate 402, (ii) the XPU 418 and the power and I/O traces 404 in the substrate 402, and (iii) the EICs 416 and the XPU 418.

In some embodiments, the components of photonics package 400 may be similar to those with similar reference numerals in photonics package 100, except as otherwise noted herein. In the illustrated embodiment, for example, the photonics package 400 includes an XPU 418 and an optical transceiver 413 on a package substrate 402 with a cavity 408. The package substrate 402 also includes conductive contacts 403 (e.g., balls, pads) below the substrate 402, conductive contacts 405 in the cavity 408, and conductive traces 404 patterned in the substrate 402 (at least some of which are connected to the conductive contacts 403, 405). The optical transceiver 413 includes a photonic integrated circuit cavity bridge (PIC-CB) 414 and multiple electronic integrated circuits (EICs) 416.

The PIC-CB 414 resides in the cavity 408 of the substrate 402 and includes typical photonic components/circuitry described herein. The PIC-CB 414 is connected to conductive contacts 405 in the cavity 408, conductive contacts 407 under the EICs 416, and conductive contacts 409 under the XPU 418. The PIC-CB 414 also includes multiple through-hole vias 412 under the EICs 416 and the XPU 418 to serve as a cavity bridge between (i) the EICs 416 and the power and I/O traces 404 in the substrate 402 and (ii) the XPU 418 and the power and I/O traces 404 in the substrate 402. In addition, the PIC-CB 414 includes conductive traces 411 connecting the EICs 416 and the XPU 418. In addition, multiple fiber arrays 415 are attached to the PIC-CB 414.

Each EIC 416 includes conductive contacts 407 on its bottom surface, which are connected to conductive contacts on the top surface of the PIC-CB 414, which in turn connect the EIC 416 to the XPU 418 and the power and I/O traces 404 in the substrate 402.

The XPU 418 includes conductive contacts 409 on its bottom surface, which are connected to the top surface of the PIC-CB 414 and may also be connected to conductive contacts on the top surface of the substrate 402 (which may in turn connect to other conductive traces in the substrate 402).

The design of photonics package 400 provides various advantages, including the advantages described for photonics packages 100, 200, and 300, along with additional advantages. For example, this design provides additional space for EIC and XPU signal routing by extending the PIC-CB 414 under both the EIC 416 and the XPU 418, which enables high density I/O connections between the EIC 416 and XPU 418. In addition, power delivery to the XPU 418 improves with direct vertical connection through the PIC-CB 414. Moreover, the XPU-to-EIC connection is through the PIC-CB 414 rather than the substrate layers 402, which results in better bandwidth. Further, this design allows better cooling of the PIC 414 under the XPU 418 and EIC 416.

It should be appreciated that the embodiments described herein are merely presented as examples. In other embodiments, certain components may be omitted, added, rearranged, or combined. For example, embodiments may include any number or combination of PICs and EICs (e.g., for higher bandwidth and/or redundancy), fibers, cavity bridges (CBs), embedded bridges, XPUs or other computing components, substrates, cavities in the substrate, conductive contacts, conductive traces, vias, integrated circuit packages, and so forth.

Further, in some embodiments, the PIC may include active electrical circuitry (e.g., an active die with transistors) in addition to photonic circuitry. For example, the PIC may include electrical circuitry to perform some or all of the typical functions of the EIC or any other electrical component.

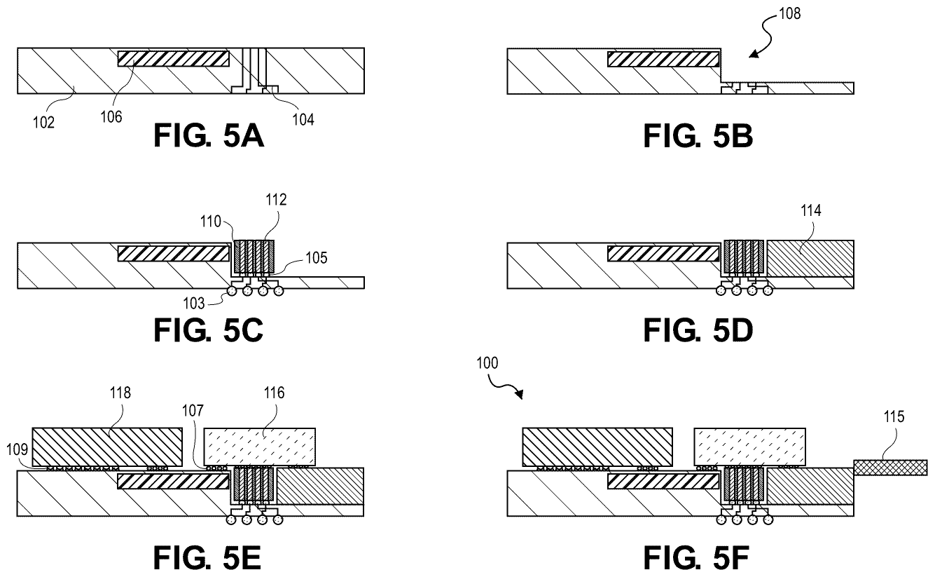

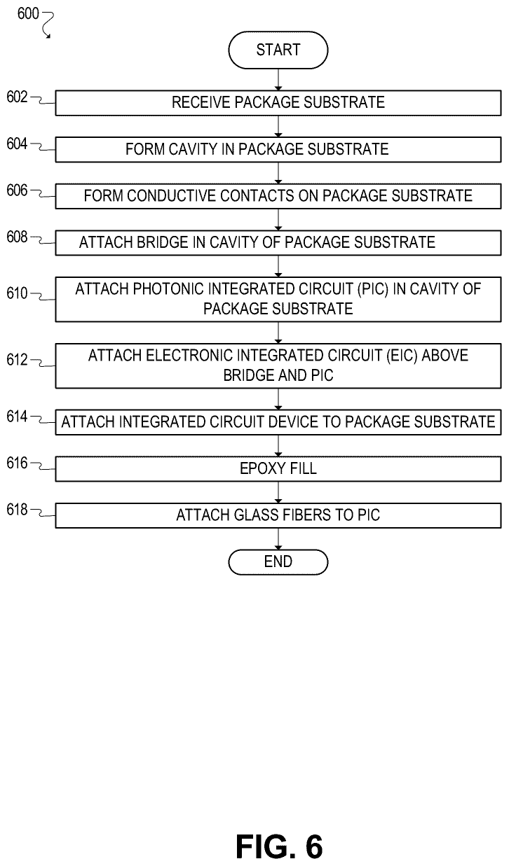

FIGS. 5A-F illustrate various stages of an example packaging process for packaging an integrated circuit device with photonics circuitry, and FIG. 6 illustrates an example process flow 600 for the packaging process of FIGS. 5A-F. In the illustrated example, the packaging process is used to form the integrated circuit package 100 of FIGS. 1A-B, although similar packaging processes can be used to form the integrated circuit packages 200, 300, 400 of FIGS. 2A-B, 3A-B, and 4A-B. Further, it will be appreciated in light of the present disclosure that the example packaging process of FIGS. 5A-F and FIG. 6 is only one example methodology for arriving at the example integrated circuit packages shown and described throughout this disclosure.

The steps of process flow 600 may be performed using any suitable semiconductor fabrication techniques. For example, film deposition-such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal-such as interconnect patterning, forming via openings, and shaping—may be performed using any suitable techniques, such as lithography-based patterning/masking and/or etching.

The process flow begins at block 602 by receiving a package substrate 102, as shown in FIG. 5A. In some embodiments, the package substrate 102 may be an organic substrate formed from one or more organic compounds or materials. In the illustrated embodiment, the package substrate 102 includes an embedded bridge 106 and conductive traces 104 patterned in the package substrate. The embedded bridge is embedded in the package substrate to serve as an interconnect between an integrated circuit device and an electronic integrated circuit (EIC) that will subsequently be attached to the package (as discussed below in connection with blocks 612 and 614). In some embodiments, for example, the embedded bridge may be an embedded multi-die interconnect bridge (EMIB). The conductive traces 104 may include any combination of conductive contacts, traces, and/or vias patterned and/or embedded in the package substrate 102. In some embodiments, the conductive traces 104 may serve as an interconnect between integrated circuit dies that will be attached to the package and/or between the package and other components, such as another integrated circuit package or a printed circuit board (e.g., a motherboard).

The process flow then proceeds to block 604 to form a cavity 108 in the package substrate (e.g., using lithography-based techniques), as shown in FIG. 5B.

The process flow then proceeds to block 606 to form conductive contacts 103, 105 below the package substrate and in the cavity of the package substrate, as shown in FIG. 5C. For example, a set of conductive contacts 103 (e.g., solder balls, pads) is formed below the package substrate to provide an interconnect for an electrical connection to a next level component, such as a printed circuit board (e.g., a motherboard) and/or another integrated circuit package. In addition, a set of conductive contacts 105 (e.g., solder balls, pads) is formed in the cavity of the package substrate to provide an interconnect for an electrical connection to a cavity bridge (as described below in connection with step 608). Further, some or all of the conductive contacts 103, 105 below the substrate and within the cavity of the substrate may be connected via the conductive traces 104 patterned in the substrate.

The process flow then proceeds to block 608 to attach a bridge 110 to the conductive contacts 105 in the cavity of the package substrate, as shown in FIG. 5C. In some embodiments, for example, the bridge may include a bridge substrate 110 patterned with conductive traces 112 (e.g., conductive contacts, conductive layers, and/or vias) to provide an interconnect for electrical connections to other components, such as the package substrate and an electronic integrated circuit (EIC) (as described below in connection with step 612). For example, the bridge substrate 110 may be a silicon substrate or glass substrate (e.g., a substrate formed from materials that include silicon or glass). Moreover, conductive contacts at the bottom of the bridge may be attached to conductive contacts in the cavity of the package substrate to form an electrical connection between the bridge and the package substrate.

The process flow then proceeds to block 610 to attach a photonic integrated circuit (PIC) 114 in the cavity of the package substrate, as shown in FIG. 5D. In some embodiments, for example, the PIC 114 may be bonded to the package substrate in the cavity (e.g., adjacent to the bridge 110).

The process flow then proceeds to block 612 to attach an electronic integrated circuit (EIC) 116 above the bridge, PIC, and package substrate, as shown in FIG. 5E. For example, conductive contacts 107 (e.g., bumps/micro-bumps) at the bottom of the EIC 116 are attached to conductive contacts on the top of the PIC, the bridge, and the package substrate to form electrical connections with those components.

The process flow then proceeds to block 614 to attach an integrated circuit (IC) device 118 to the package substrate, as shown in FIG. 5E. For example, conductive contacts 109 (e.g., bumps/micro-bumps) on the bottom of the IC device 118 are attached to conductive contacts on top of the package substrate 102 (e.g., adjacent/external to the cavity 108) to form an electrical connection with the package substrate 102.

The IC device 118 may include any type of integrated circuit device or computing component, including, but not limited to, a microcontroller, a microprocessor, a central processing unit (CPU), a graphics processing unit (GPU), a vision processing unit (VPU), a tensor processing unit (TPU), an application-specific integrated circuit (ASIC), a field-programmable gate array (FPGA), a switch, a network interface controller (NIC), a memory device (e.g., memory, memory controller), and/or a persistent storage device (e.g., hard disk drive (HDD), solid state drive (SSD)), among other examples.

The process flow then proceeds to block 616 to fill empty space with an epoxy (not shown).

The process flow then proceeds to block 618 to attach glass fibers 115 to the PIC, as shown in FIG. 5F, which enables the PIC 114 to send or receive optical signals via the glass gibers.

The completed integrated circuit package 100 is shown in FIG. 5F. In the completed package 100, the cavity bridge 110 has direct electrical connections to the interconnect 103 on the bottom of the package substrate 102 and the EIC 116.

The EIC 116 has direct electrical connections to the cavity bridge 110, the PIC 114, and the embedded bridge 106 in the package substrate 102. The EIC 116 also has indirect electrical connections to the interconnect 103 on the bottom of the package substrate 102 and the IC device 118. For example, the EIC 116 is indirectly connected to the bottom interconnect 103 via the cavity bridge 110, and the EIC 116 is indirectly connected to the IC device 118 via the embedded bridge 106.

The PIC 114 has a direct electrical connection to the EIC 116, along with an indirect electrical connection to the interconnect 103 on the bottom of the package substrate 102 via the EIC 116 and the cavity bridge 110.

The IC device 118 has a direct electrical connection to the embedded bridge 106 in the package substrate 102, along with an indirect electrical connection to the EIC 116 via the embedded bridge 106. The IC device 118 may also have direct or indirect electrical connections to the interconnect 103 on the bottom of the package substrate 102 (not shown).

At this point, the process flow may be complete. In some embodiments, however, the process flow may restart and/or certain blocks may be repeated. For example, in some embodiments, the process flow may restart at block 602 to continue packaging another integrated circuit device with photonics circuitry.

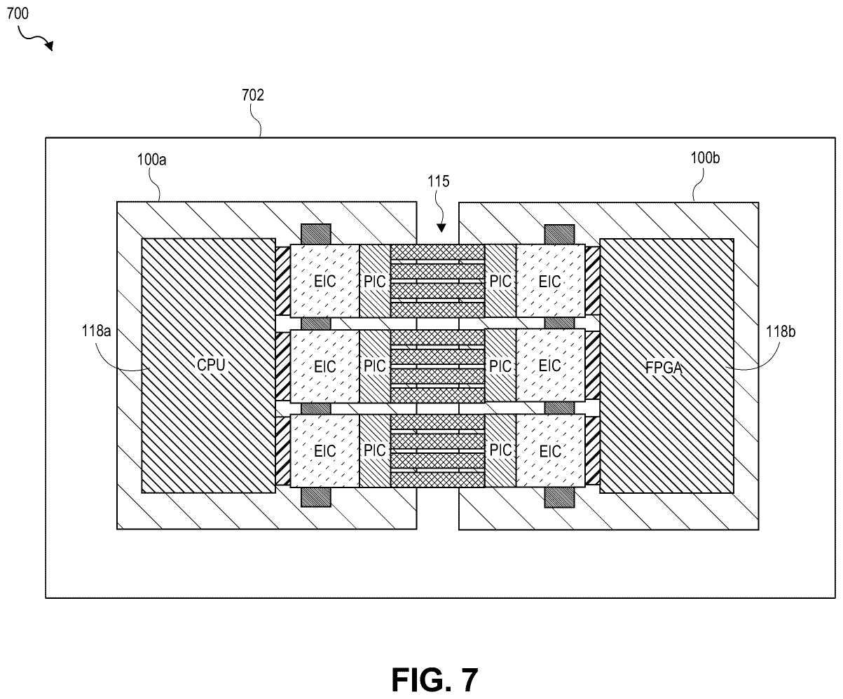

FIG. 7 illustrates an example system 700 with computing components that are packaged with optical transceivers in multi-chip packages. In the illustrated embodiment, system 700 includes a printed circuit board (PCB) 702 with multiple integrated circuit (IC) packages 100a-b attached to the board. The IC packages 100a-b are instances of the IC package 100 of FIGS. 1A-B.

In the illustrated example, IC package 100a includes a central processing unit (CPU) 118a and IC package 100b includes a field-programmable gate array (FPGA) 118b, each of which is packaged with a photonic integrated circuit (PIC) and electronic integrated circuit (EIC) for optical input/output (I/O). For example, the CPU 118a and the FPGA 118b communicate over an optical interconnect 115 formed by a collection of glass fibers attached to the respective PICs of the IC packages 100a-b.

While a CPU and FPGA are depicted in the illustrated example, other embodiments may include any type, number, and/or combination of computing components packaged with optical transceivers to communicate over an optical interconnect. In some embodiments, for example, multiple processors may be packaged with optical transceivers to communicate over an optical processor interconnect in a multi-processor system (e.g., CPUs, processor cores, microprocessors, microcontrollers). Additionally, or alternatively, processors and/or input/output (I/O) devices may be packaged with optical transceivers to communicate over an optical I/O interconnect (e.g., CPUs, GPUs, VPUs, TPUs, ASICs, FPGAs, switches, NICs, persistent storage devices). Additionally, or alternatively, memory and/or memory controllers may be packaged with optical transceivers to communicate over an optical memory bus. Further, while the optical transceivers are shown on the same board in the illustrated embodiment, in other embodiments they may be on different boards and/or part of different devices (e.g., in a datacenter application, the boards could be in the same blade, different blades in a rack, or even different racks).

### Example Integrated Circuit Embodiments

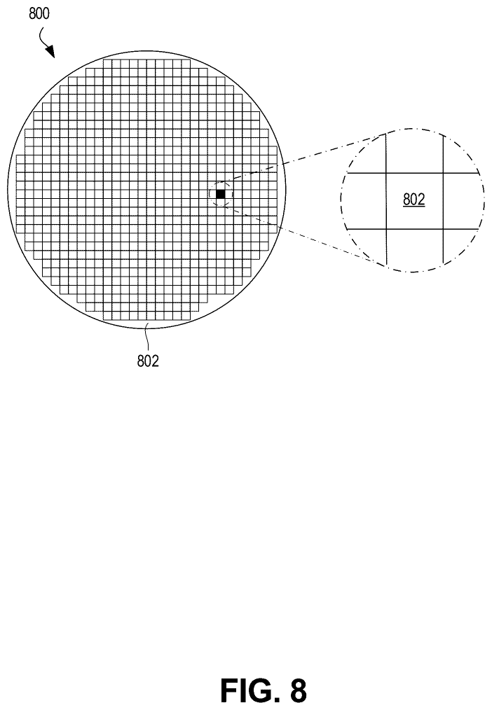

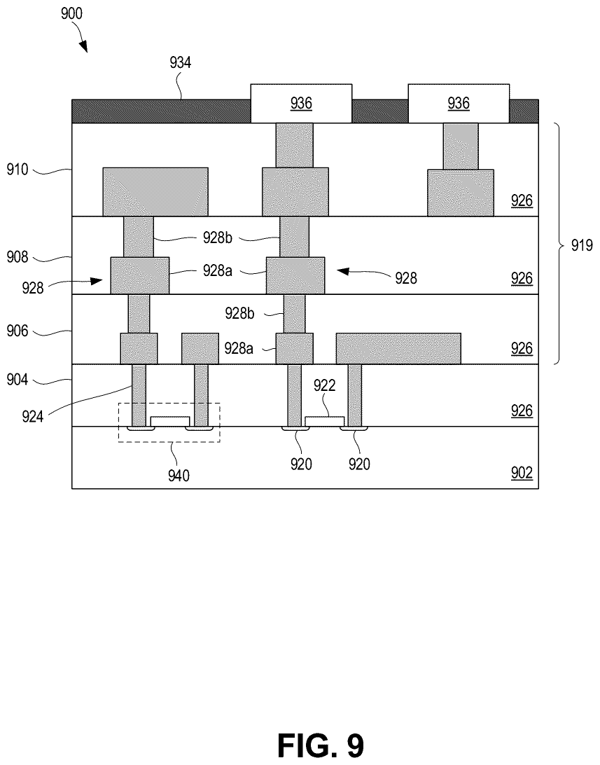

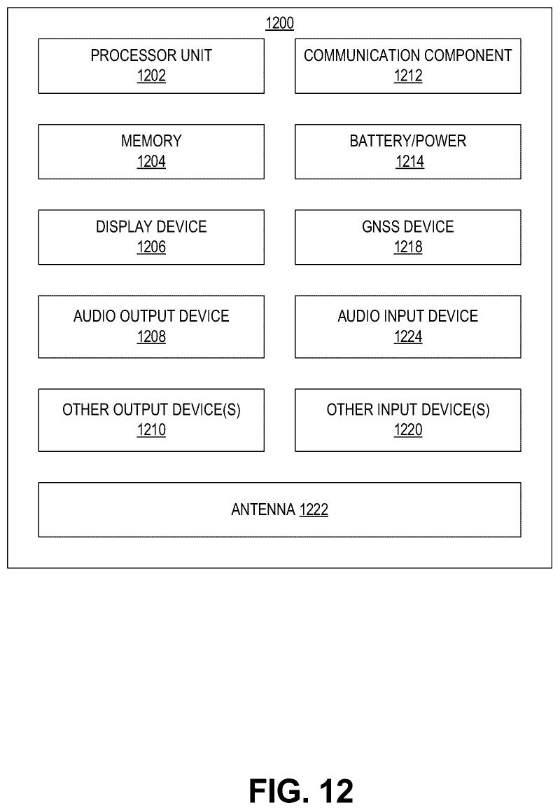

FIG. 8 is a top view of a wafer 800 and dies 802 that may be included in any of the embodiments disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may be any of the dies disclosed herein. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1202 of FIG. 12) or other logic that is configured to store information in the memory devices or execute instructions stored in the memory array. Various ones of the microelectronic assemblies disclosed herein may be manufactured using a die-to-wafer assembly technique in which some dies are attached to a wafer 800 that include others of the dies, and the wafer 800 is subsequently singulated.

FIG. 9 is a cross-sectional side view of an integrated circuit device 900 that may be included in any of the embodiments disclosed herein (e.g., in any of the dies). One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board). The integrated circuit device 900 may include additional or alternate structures to route the electrical signals from the interconnect layers 906-910; for example, the conductive contacts 936 may include other analogous features (e.g., posts) that route the electrical signals to external components. The conductive contacts 936 may serve as any of the conductive contacts described throughout this disclosure.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936. These additional conductive contacts may serve as any of the conductive contacts described throughout this disclosure.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. These additional conductive contacts may serve as any of the conductive contacts described throughout this disclosure. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

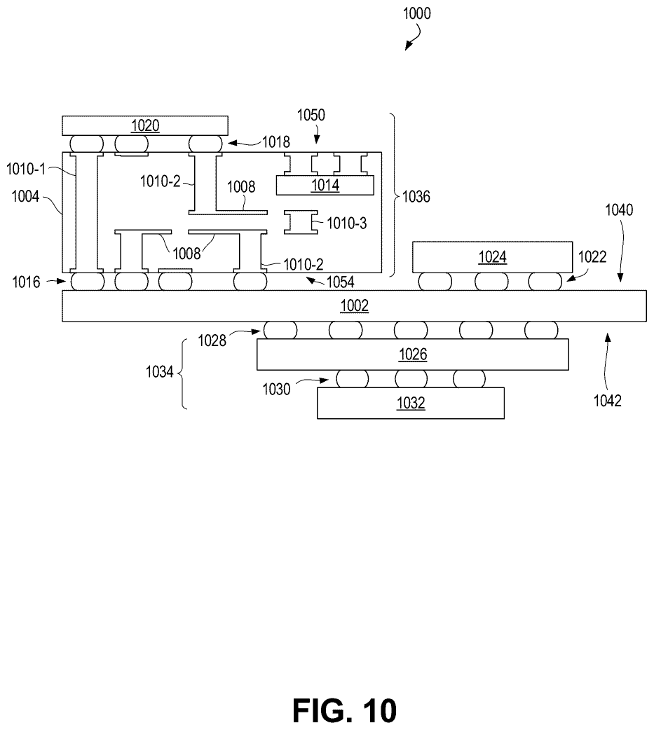

FIG. 10 is a cross-sectional side view of an integrated circuit device assembly 1000 that may include any of the embodiments disclosed herein. In some embodiments, the integrated circuit device assembly 1000 may be a microelectronic assembly. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042. Any of the integrated circuit components discussed below with reference to the integrated circuit device assembly 1000 may take the form of any suitable ones of the embodiments of the microelectronic assemblies disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1016 may serve as the coupling components illustrated or described for any of the substrate assembly or substrate assembly components described herein, as appropriate.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpacked integrated circuit product that includes one or more integrated circuit dies (e.g., the die 802 of FIG. 8, the integrated circuit device 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel@embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art. In embodiments where the interposer is a non-printed circuit board

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a cross-sectional view of an example bridge 1100 embedded within a first substrate component. The first substrate component 1104 comprises dielectric layers 1106. A first integrated circuit die 1108 is attached to a face 1112 of the substrate component 1104 via coupling components 1156 connecting to die conductive contacts 1164 and substrate conductive contacts 1110. A second integrated circuit die 1116 is attached to the face 1112 via coupling components 1160 connecting to die conductive contacts 1166 and substrate conductive contacts 1120.

Bridge conductive contacts 1124 and 1126 are located on a face 1128 of the bridge 1100. Bridge vias 1132 and bridge conductive traces 1136 provide conductive pathways between the conductive contacts 1124 and 1126. Substrate vias 1140 and substrate conductive traces 1144 provide conductive pathways from the substrate conductive contacts 1110 to the bridge conductive contacts 1124 and substrate vias 1148 and substrate conductive traces 1152 provide conductive pathways from the substrate conductive contacts 1120 to the bridge conductive contacts 1126. Together, conductive contacts 1110, 1120, 1124, 1126, vias 1132, 1140, 1148, and conductive traces, 1136, 1144, 1152 provide conductive pathways between integrated circuit dies 1108 and 1116 and thus allow them to be communicatively coupled.

Although the embedded bridge 1100 is shown as being fully embedded within the substrate component 1104, in some embodiments, it can be partially embedded, with the bridge face 1128 being part of the face 1112 of the first substrate component 1104. In such embodiments, the bridge conductive contacts 1124 and 1126 can be located at the face 1112 of the substrate component 1104 and the integrated circuit dies 1108 and 1112 can connect to the bridge conductive contacts 1124 and 1126 via coupling components 1156 and 1160, respectively.

FIG. 12 is a block diagram of an example electronic device 1200 that may include one or more of the embodiments disclosed herein. For example, any suitable ones of the components of the electronic device 1200 may include one or more of the integrated circuit packages 100, 200, 300, 400, integrated circuit device assemblies 1000, integrated circuit components 1020, integrated circuit devices 900, integrated circuit dies 802, or embedded bridges 1100 disclosed herein. In some embodiments, for example, the electronic device 1200 and/or its respective components (e.g., processor units 1202, input/output (I/O) devices 1210, 1220, communication components 1212, memory 1204) may include an integrated circuit package with an integrated circuit device packaged with photonics circuitry according to any of the embodiments described herein. A number of components are illustrated in FIG. 12 as included in the electronic device 1200, but any one or more of these components may be omitted or duplicated, as suitable for the application. In some embodiments, some or all of the components included in the electronic device 1200 may be attached to one or more motherboards mainboards, or system boards. In some embodiments, one or more of these components are fabricated onto a single system-on-a-chip (SoC) die.

Additionally, in various embodiments, the electronic device 1200 may not include one or more of the components illustrated in FIG. 12, but the electronic device 1200 may include interface circuitry for coupling to the one or more components. For example, the electronic device 1200 may not include a display device 1206, but may include display device interface circuitry (e.g., a connector and driver circuitry) to which a display device 1206 may be coupled. In another set of examples, the electronic device 1200 may not include an audio input device 1224 or an audio output device 1208, but may include audio input or output device interface circuitry (e.g., connectors and supporting circuitry) to which an audio input device 1224 or audio output device 1208 may be coupled.

The electronic device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electronic device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electronic device 1200 can comprise one or more processor units 1202 that are heterogeneous or asymmetric to another processor unit 1202 in the electronic device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electronic device 1200.

In some embodiments, the electronic device 1200 may include a communication component 1212 (e.g., one or more communication components). For example, the communication component 1212 can manage wireless communications for the transfer of data to and from the electronic device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electronic device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electronic device 1200 may include battery/power circuitry 1214. The battery/power circuitry 1214 may include one or more energy storage devices (e.g., batteries or capacitors) and/or circuitry for coupling components of the electronic device 1200 to an energy source separate from the electronic device 1200 (e.g., AC line power).

The electronic device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electronic device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electronic device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electronic device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electronic device 1200 based on information received from one or more GNSS satellites, as known in the art.

The electronic device 1200 may include other output device(s) 1210 (or corresponding interface circuitry, as discussed above). Examples of the other output device(s) 1210 may include an audio codec, a video codec, a printer, a wired or wireless transmitter for providing information to other devices, or an additional storage device.

The electronic device 1200 may include other input device(s) 1220 (or corresponding interface circuitry, as discussed above). Examples of the other input device(s) 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electronic device 1200 may have any desired form factor, such as a hand-held or mobile electronic device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electronic device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electronic device or an embedded computing system (e.g., computing systems that are part of a vehicle, smart home appliance, consumer electronics product or equipment, manufacturing equipment). In some embodiments, the electronic device 1200 may be any other electrical or electronic device that processes data. In some embodiments, the electronic device 1200 may comprise multiple discrete physical components. Given the range of devices that the electronic device 1200 can be manifested as in various embodiments, in some embodiments, the electronic device 1200 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The terms “top,” “bottom,” “above,” “below,” “over,” “under,” “to,” “between,” and “on” as used herein may refer to a relative position of one layer or component with respect to other layers or components. One layer “over” or “on” another layer or bonded “to” another layer may be directly in contact with the other layer or may have one or more intervening layers. One layer “between” layers may be directly in contact with the layers or may have one or more intervening layers. However, it is understood that embodiments are not necessarily limited to the orientations or configurations illustrated in the figures.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

### Example Embodiments

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an integrated circuit package, comprising: a package substrate having a cavity; an integrated circuit device electrically coupled to the package substrate; a bridge electrically coupled to the package substrate, wherein the bridge is in the cavity of the package substrate; a photonic integrated circuit (PIC) to send or receive optical signals, wherein the PIC is in the cavity of the package substrate; and an electronic integrated circuit (EIC) electrically coupled to the bridge and the PIC, wherein the EIC is above the bridge and the PIC.

Example 2 includes the integrated circuit package of Example 1, further comprising a first bridge and a second bridge, wherein: the first bridge is the bridge in the cavity of the package substrate; and the second bridge is embedded in the package substrate, wherein the integrated circuit device and the EIC are electrically coupled via the second bridge.

Example 3 includes the integrated circuit package of Example 2, wherein the first bridge is embedded in the PIC.

Example 4 includes the integrated circuit package of Example 1, wherein the integrated circuit device and the EIC are electrically coupled via the bridge.

Example 5 includes the integrated circuit package of Example 4, wherein the integrated circuit device is electrically coupled to the package substrate via the bridge.

Example 6 includes the integrated circuit package of any of Examples 4-5, wherein the bridge is embedded in the PIC.

Example 7 includes the integrated circuit package of any of Examples 1-6, wherein the bridge comprises: a bridge substrate; and one or more through-hole vias within the bridge substrate, wherein the EIC is electrically coupled to the package substrate via the one or more through-hole vias.

Example 8 includes the integrated circuit package of Example 7, wherein: the package substrate comprises an organic material; and the bridge substrate comprises silicon or glass.

Example 9 includes the integrated circuit package of any of Examples 1-8, wherein: the bridge is embedded in the PIC; and the PIC is electrically coupled to the package substrate via a set of conductive contacts in the cavity of the package substrate.

Example 10 includes the integrated circuit package of any of Examples 1-9, further comprising: a plurality of glass fibers coupled to the PIC, wherein the PIC is to send or receive the optical signals via the plurality of glass fibers.

Example 11 includes the integrated circuit package of any of Examples 1-10, further comprising: a plurality of conductive traces embedded in the package substrate; a first set of conductive contacts below the package substrate; a second set of conductive contacts in the cavity of the package substrate, wherein the bridge is electrically coupled to the second set of conductive contacts, and wherein the second set of conductive contacts are electrically coupled to the first set of conductive contacts via the plurality of conductive traces; and a third set of conductive contacts below the EIC, wherein the EIC is electrically coupled to the bridge via the third set of conductive contacts.

Example 12 includes the integrated circuit package of Example 11, further comprising: a fourth set of conductive contacts below the EIC, wherein the EIC is electrically coupled to the PIC via the fourth set of conductive contacts.

Example 13 includes the integrated circuit package of any of Examples 1-12, wherein the integrated circuit device comprises: a microcontroller; a microprocessor; a central processing unit; a graphics processing unit; a vision processing unit; a tensor processing unit; an application-specific integrated circuit; a field-programmable gate array; a switch; a network interface controller; a memory device; or a persistent storage device.

Example 14 includes an electronic device, comprising: a printed circuit board; an optical interconnect, wherein the optical interconnect comprises a plurality of glass fibers; and a plurality of integrated circuit packages coupled to the printed circuit board, wherein a plurality of integrated circuit devices are packaged within the plurality of integrated circuit packages, and wherein individual integrated circuit packages comprise: a package substrate having a cavity; an integrated circuit device electrically coupled to the package substrate, wherein the integrated circuit device is one of the plurality of integrated circuit devices; a bridge electrically coupled to the package substrate, wherein the bridge is in the cavity of the package substrate; and an optical transceiver to send or receive optical signals via the optical interconnect, wherein the optical transceiver comprises: a photonic integrated circuit (PIC) coupled to the optical interconnect, wherein the PIC is in the cavity of the package substrate; and an electronic integrated circuit (EIC) electrically coupled to the bridge and the PIC, wherein the EIC is above the bridge and the PIC.

Example 15 includes the electronic device of Example 14, wherein the plurality of integrated circuit devices comprise: one or more processing devices; one or more memory devices; one or more storage devices; or one or more communication devices.

Example 16 includes the electronic device of Example 15, wherein the one or more processing devices comprise: a microcontroller; a microprocessor; a central processing unit; a graphics processing unit; a vision processing unit; a tensor processing unit; an application-specific integrated circuit; or a field-programmable gate array.

Example 17 includes the electronic device of any of Examples 15-16, wherein the one or more communication devices comprise: a switch; or a network interface controller.

Example 18 includes a method of forming an integrated circuit package, comprising: forming a cavity in a package substrate; attaching a bridge to the package substrate within the cavity, wherein conductive contacts on the bridge are attached to conductive contacts on the package substrate; attaching a photonic integrated circuit (PIC) to the package substrate within the cavity; attaching an electronic integrated circuit (EIC) on top of the bridge and the PIC, wherein conductive contacts on the EIC are attached to conductive contacts on the bridge and conductive contacts on the PIC; and attaching an integrated circuit device to the package substrate, wherein conductive contacts on the integrated circuit device are attached to conductive contacts on the package substrate.

Example 19 includes the method of Example 18, further comprising: attaching a plurality of glass fibers to the PIC.

Example 20 includes the method of any of Examples 18-19, further comprising: forming conductive contacts below the package substrate.

1. An integrated circuit package, comprising:
a package substrate having a cavity;
an integrated circuit device electrically coupled to the package substrate;
a bridge electrically coupled to the package substrate, wherein the bridge is in the cavity of the package substrate;
a photonic integrated circuit (PIC) to send or receive optical signals, wherein the PIC is in the cavity of the package substrate; and
an electronic integrated circuit (EIC) electrically coupled to the bridge and the PIC, wherein the EIC is above the bridge and the PIC.

2. The integrated circuit package of claim 1, further comprising a first bridge and a second bridge, wherein:
the first bridge is the bridge in the cavity of the package substrate; and
the second bridge is embedded in the package substrate, wherein the integrated circuit device and the EIC are electrically coupled via the second bridge.

3. The integrated circuit package of claim 2, wherein the first bridge is embedded in the PIC.

4. The integrated circuit package of claim 1, wherein the integrated circuit device and the EIC are electrically coupled via the bridge.

5. The integrated circuit package of claim 4, wherein the integrated circuit device is electrically coupled to the package substrate via the bridge.

6. The integrated circuit package of claim 4, wherein the bridge is embedded in the PIC.

7. The integrated circuit package of claim 1, wherein the bridge comprises:
a bridge substrate; and
one or more through-hole vias within the bridge substrate, wherein the EIC is electrically coupled to the package substrate via the one or more through-hole vias.

8. The integrated circuit package of claim 7, wherein:
the package substrate comprises an organic material; and
the bridge substrate comprises silicon or glass.

9. The integrated circuit package of claim 1, wherein:
the bridge is embedded in the PIC; and
the PIC is electrically coupled to the package substrate via a set of conductive contacts in the cavity of the package substrate.

10. The integrated circuit package of claim 1, further comprising:
a plurality of glass fibers coupled to the PIC, wherein the PIC is to send or receive the optical signals via the plurality of glass fibers.

11. The integrated circuit package of claim 1, further comprising:
a plurality of conductive traces embedded in the package substrate;
a first set of conductive contacts below the package substrate;
a second set of conductive contacts in the cavity of the package substrate, wherein the bridge is electrically coupled to the second set of conductive contacts, and wherein the second set of conductive contacts are electrically coupled to the first set of conductive contacts via the plurality of conductive traces; and
a third set of conductive contacts below the EIC, wherein the EIC is electrically coupled to the bridge via the third set of conductive contacts.

12. The integrated circuit package of claim 11, further comprising:
a fourth set of conductive contacts below the EIC, wherein the EIC is electrically coupled to the PIC via the fourth set of conductive contacts.

13. The integrated circuit package of claim 1, wherein the integrated circuit device comprises:
a microcontroller;
a microprocessor;
a central processing unit;
a graphics processing unit;
a vision processing unit;
a tensor processing unit;
an application-specific integrated circuit;
a field-programmable gate array;
a switch;
a network interface controller;
a memory device; or
a persistent storage device.

14. An electronic device, comprising:
a printed circuit board;
an optical interconnect, wherein the optical interconnect comprises a plurality of glass fibers; and
a plurality of integrated circuit packages coupled to the printed circuit board, wherein a plurality of integrated circuit devices are packaged within the plurality of integrated circuit packages, and wherein individual integrated circuit packages comprise:
a package substrate having a cavity;
an integrated circuit device electrically coupled to the package substrate, wherein the integrated circuit device is one of the plurality of integrated circuit devices;
a bridge electrically coupled to the package substrate, wherein the bridge is in the cavity of the package substrate; and
an optical transceiver to send or receive optical signals via the optical interconnect, wherein the optical transceiver comprises:
a photonic integrated circuit (PIC) coupled to the optical interconnect, wherein the PIC is in the cavity of the package substrate; and
an electronic integrated circuit (EIC) electrically coupled to the bridge and the PIC, wherein the EIC is above the bridge and the PIC.

15. The electronic device of claim 14, wherein the plurality of integrated circuit devices comprise:
one or more processing devices;
one or more memory devices;
one or more storage devices; or
one or more communication devices.

16. The electronic device of claim 15, wherein the one or more processing devices comprise:
a microcontroller;
a microprocessor;
a central processing unit;
a graphics processing unit;
a vision processing unit;
a tensor processing unit;
an application-specific integrated circuit; or
a field-programmable gate array.

17. The electronic device of claim 15, wherein the one or more communication devices comprise:
a switch; or
a network interface controller.

18. A method of forming an integrated circuit package, comprising:
forming a cavity in a package substrate;
attaching a bridge to the package substrate within the cavity, wherein conductive contacts on the bridge are attached to conductive contacts on the package substrate;
attaching a photonic integrated circuit (PIC) to the package substrate within the cavity;
attaching an electronic integrated circuit (EIC) on top of the bridge and the PIC, wherein conductive contacts on the EIC are attached to conductive contacts on the bridge and conductive contacts on the PIC; and
attaching an integrated circuit device to the package substrate, wherein conductive contacts on the integrated circuit device are attached to conductive contacts on the package substrate.

19. The method of claim 18, further comprising:
attaching a plurality of glass fibers to the PIC.

20. The method of claim 18, further comprising:
forming conductive contacts below the package substrate.
